(19) United States
(12) Patent Application Publication
(10) Pub. No.: US 2025/0231257 A1
(43) Pub. Date: Jul. 17, 2025

(54) METHOD FOR TESTING A GROUND CONTACT UNIT, AND ELECTRIC CHARGING INFRASTRUCTURE

(71) Applicant: Easelink GmbH, Graz (AT)

(72) Inventors: Andreas SULZENBACHER, Graz (AT); Fabian LUTTENBERGER, Graz (AT); Friedrich LOBENSTOCK, Graz (AT); Hermann STOCKINGER, Graz (AT)

(21) Appl. No.: 18/853,754

(22) PCT Filed: Apr. 3, 2023
(86) PCT No.: PCT/EP2023/058716

§ 371 Date: Nov. 22, 2024

(30) Foreign Application Priority Data
Apr. 4, 2022 (DE) 10 2022 108 023.4

(51) Int. Cl. G01R 31/68; B60L 53/12; B60L 53/62; G01R 31/14

(52) U.S. Cl. CPC G01R 31/68; B60L 53/12; B60L 53/62; G01R 31/14

(57) ABSTRACT

A method of checking a ground contact unit of an electric charging infrastructure. The ground contact unit has a plate-shaped base body and a plurality of contacts arranged on a charging surface of the base body, against which a vehicle contact unit can rest. The method includes performing a contacting check to determine whether at least a subset of the contacts is contacted, performing a protective conductor check to ascertain a contact quality by passing a test current across at least one of the contacts, and performing continuous touch protection monitoring by continuously monitoring switching positions of the contact switches assigned to power contacts that are not part of the subset of the contacted contacts, and/or by continuously monitoring an existing contacting of at least one contact that is part of the subset of the contacted contacts and/or by performing a voltage measurement on at least one of the contacts.

### FIELD OF THE INVENTION

The invention relates to a method of checking a ground contact unit of an electric charging infrastructure. The invention further relates to an electric charging infrastructure for establishing a conductive connection to a vehicle contact unit.

### BACKGROUND

In at least partly electrically powered vehicles, for example plug-in hybrid vehicles and purely electric vehicles, the batteries of the vehicles have to be charged regularly, preferably after each journey. To this end, the vehicle is connected to an appropriate power source, usually using a plug, for example a so-called type 2 plug, which a person has to manually plug into a corresponding socket on the vehicle.

The prior art, for example WO 2019/052962 A1, furthermore discloses ground contact units for vehicle battery charging systems, which are provided on the ground. To charge the vehicle, the ground contact units can automatically establish a conductive connection with a corresponding vehicle contact unit provided on the vehicle to be charged. The vehicle contact unit may be provided on the underbody of the vehicle; it moves downward to establish the electrical contacting with the ground contact unit.

The ground contact unit is, for example, designed as a so-called matrix charging pad, as is shown in WO 2019/052962 A1. For this purpose, the ground contact unit comprises a multitude of contact areas in a matrix-like arrangement, the contact areas being adapted to be contacted by means of the vehicle contact unit in order to establish an electrical connection between the ground contact unit and the vehicle contact unit. Depending on the point of ground contact of the connector of the vehicle contact unit, the respective occupied contact areas of the ground contact unit are connected in order to establish the electrical connection via these contact areas.

Typically, the occupied contact areas are connected by means of separate relays that are assigned to each power contact of the ground contact unit. This results in a so-called matrix relay, which ensures, among other things, the safety-relevant requirements with regard to the insulation distance of the individual switches. Irrespective of the switching positions of the relays, however, there are further aspects to consider in order to allow a charging process.

### SUMMARY

It is the object to cost-effectively and efficiently check the ground contact unit of the electric charging infrastructure with regard to its readiness.

The object is achieved in accordance with the invention by a method of checking a ground contact unit of an electric charging infrastructure, wherein the ground contact unit has a plate-shaped base body and a plurality of contacts which are arranged on a charging surface of the base body, against which a vehicle contact unit can come to rest. The plurality of contacts include at least one protective conductor contact and power contacts which are assigned to at least one potential level by means of at least one contact switch. The method further includes the steps of:
performing a contacting check to determine whether at least a subset of the plurality of contacts of the ground contact unit is contacted;
performing a protective conductor check to ascertain a contact quality by passing a test current across at least one contact of the plurality of contacts; and
performing continuous touch protection monitoring of the contacts by continuously monitoring switching positions of the contact switches which are assigned to power contacts that are not part of the subset of the contacted contacts, and/or by continuously monitoring an existing contacting of at least one contact that is part of the subset of the contacted contacts and/or by performing a voltage measurement on at least one of the contacts.

Furthermore, the object is achieved in accordance with the invention by an electric charging infrastructure for establishing a conductive connection to a vehicle contact unit. The charging infrastructure includes a ground contact unit which has a plate-shaped base body and a plurality of contacts which are arranged on a charging surface of the base body, against which the vehicle contact unit can come to rest. The plurality of contacts include at least one protective conductor contact and power contacts which are assigned to at least one potential level by means of at least one contact switch. The charging infrastructure includes a checking system which is configured to
perform a contacting check to determine whether at least a subset of the plurality of contacts of the ground contact unit is contacted;
perform a protective conductor check to ascertain a contact quality, wherein the checking system is configured to pass a test current across at least one contact of the plurality of contacts; and
perform a continuous touch protection monitoring of the contacts, the checking system being configured to continuously monitor switching positions of the contact switches which are assigned to power contacts that are not part of the subset of the contacted contacts, and/or to continuously monitor an existing contacting of at least one contact that is part of the subset of the contacted contacts, and/or to perform a voltage measurement on at least one of the contacts.

According to the invention, it is provided that a plurality of checks take place before a charging current is passed across the power contacts in order to charge a vehicle the vehicle contact unit of which is coupled to the corresponding ground contact unit. The checks involve, among other things, the contacting check, which is carried out to determine whether the contacts of the ground contact unit are contacted at all, that is, whether there is a conductive connection to the vehicle contact unit. In addition, during the protective conductor check, not only is the continuity checked, but the corresponding contact quality is determined in order to ascertain whether the contacting meets specific minimum requirements so that a charging process can be started.

Moreover, a touch protection monitoring is performed to ensure that unintentional contacting of accessible contacts of the ground contact unit is possible. Touch protection monitoring is performed continuously during conductive charging. But it may additionally also be provided that the touch protection monitoring is performed immediately prior to the charging process.

To this end, provision is made, for example, that during the continuous touch protection monitoring, the respective switching positions of the contact switches are monitored which are associated with the power contacts that are not contacted. These are the power contacts that are not part of the subset of the contacted contacts, which is why they are accessible from the outside. These accessible contacts may also be referred to as exposed contacts, since they are not covered by the vehicle contact unit when the conductive connection has been made. The touch protection monitoring by means of the switching positions of the contact switches is used to check whether the respective power contacts are switched potential-free, as is intended for the exposed power contacts, that is, those power contacts that do not establish the conductive connection with the vehicle contact unit.

Alternatively or additionally, the continuous touch protection monitoring may consist in continuously monitoring whether the conductive connection already established is maintained or whether the conductive connection established has been broken. For this purpose, it may be sufficient if at least one of the contacts of the subset is checked, since this contact had previously been contacted. Basically, the at least one contact of the subset that is utilized for the continuous touch protection check may be a power contact or a protective conductor contact of the plurality of contacts, provided that a corresponding signal is applied and evaluated, for example a high-frequency signal that is fed in (“RF loop”). However, further types of contact may also be provided that are made use of for continuous monitoring, for example a control contact across which an appropriate control signal is routed that is monitored.

Continuous touch protection monitoring may be effected with the aid of a monitoring circuit that monitors the switching positions of the contact switches and/or the continuous contacting of the respective contact of the subset, that is, e.g. the control signal.

Alternatively or additionally, provision may be made to carry out a voltage measurement on at least one contact, in particular on a power contact. This at least one contact may be referred to as a monitored contact.

A measuring circuit may be provided for this purpose, which is configured to carry out the voltage measurement on the at least one contact.

In particular, the measuring circuit is configured to detect an inadmissibly applied voltage at the monitored contact.

The measuring circuit may be formed as part of the monitoring circuit or separately therefrom.

The measuring circuit may therefore be used to form a touch protection since an inadmissibly applied voltage would be detected.

Generally, it may be provided that the ground contact unit features a continuous surface that forms the protective conductor contact, i.e. provides a so-called protective conductor plane, which is interrupted by, inter alia, the power contacts. In other words, the charging surface is formed for the most part by the protective conductor contact, with the respective power contacts being arranged in the plane formed by the protective conductor contact, in particular with a ring-shaped insulating area to electrically insulate the power contacts from the protective conductor contact, that is, the respective protective conductor plane.

The protective conductor check is provided to check the contact quality of a conductive connection that has been established, by passing a test current through at least one of the contacts. The appropriate test current may be provided by the ground contact unit. Alternatively, provision may be made for a current source of the motor vehicle to be used to provide the test current, which is then passed across the at least one contact of the ground contact unit starting from the vehicle contact unit, which is conductively connected to the ground contact unit. The measurement of the respective test current, in particular an associated resistance measurement to determine the contact quality, may also be performed in the ground contact unit itself or in the vehicle, which is electrically connected to the ground contact unit through its vehicle contact unit, provided that the conductive connection exists between the vehicle contact unit and the ground contact unit.

In particular, the protective conductor check is performed before a charging process is carried out.

The checks ensure that the ground contact unit is ready for a charging process. If the checks have been successfully completed, a charging process can be performed in that a charging current flows from the ground contact unit and the vehicle contact unit connected thereto through the appropriately switched power contacts.

During the charging process, and optionally before the charging current flows for the first time, the touch protection check may be carried out continuously to ensure that the contacts not required for the charging process, in particular the accessible power contacts, can be touched or that the continuity of the contacts of the subset, i.e. the contacted contacts, is given. In other words, it would be detected if an existing contact between the vehicle contact unit and the ground contact unit were to break during the charging process.

One aspect provides that the subset of the plurality of contacts is associated with a contacting area of the charging surface, which is covered by a component of the vehicle contact unit when a conductive connection is established between the ground contact unit and the vehicle contact unit. The respective subset, that is, the number of the plurality of contacts located in the contacting area of the charging surface, depends on the size of the ground contact unit and/or the size of the corresponding component of the vehicle contact unit, which interacts with the contacts of the ground contact unit for making the conductive connection.

In an extreme example, it may be provided that all contacts of the ground contact unit are occupied, which means that there are no exposed contacts in the contacted state. Accordingly, the subset of the plurality of contacts may be all the contacts of the ground contact unit. Typically, however, the ground contact unit includes more contacts than the contacts required for the conductive connection between the ground contact unit and the vehicle contact unit. This ensures, among other things, that the motor vehicle need not come to a stop exactly over a specific area of the ground contact unit, thus providing greater flexibility. The component of the vehicle contact unit that covers the contacting area may be a movable part of the vehicle contact unit, for example a movable charging nozzle or the like, which, starting from an underbody of the motor vehicle, is moved toward the ground contact unit to establish the conductive connection.

According to a further aspect, an insulation check is carried out between two contacts by applying a test voltage and measuring an insulation resistance which is compared with an insulation resistance threshold value. The insulation check may also be carried out before the charging process takes place, so that the insulation check differs from a monitoring of the charging process by means of a residual current device. The insulation check is of advantage in particular if the ground contact unit is used in an area that is exposed to external influences, in particular moisture and/or dirt, that is, for example in an uncovered parking lot.

For example, the two contacts that are used in the insulation check are neighboring contacts on the charging surface, in particular two contacts of the subset. The insulation check can therefore be carried out between two contacts that are directly adjacent to each other, since an (inadvertent) conductive connection is most likely to occur between neighboring contacts, for example through an object, dirt or moisture. In particular, contacts that are part of the subset can be used in the insulation check. In this respect, the insulation is measured between two contacts that are utilized to form the conductive connection. In particular, the insulation check is carried out between two power contacts. Alternatively, it may be provided that the insulation check is carried out between at least one power contact and the at least one protective conductor contact.

For example, in the case of a protective conductor plane, it may be provided that all power contacts are switched to a common potential, with the insulation between the power contacts at the common potential then being measured in relation to the protective conductor plane.

In an alternative configuration, it may be provided that the insulation check is carried out one after the other for different pairings of contacts in order to ensure that sufficient insulation is provided.

For example, the test voltage for the insulation check is at least 500 V. The insulation resistance threshold value is 0.25 MΩ, for example.

A further aspect provides that the insulation check is only carried out if it has been previously determined that at least the subset of the plurality of contacts is contacted. In this respect, the insulation check is only carried out if there is a conductive connection between the ground contact unit and the vehicle contact unit. In addition, during the insulation check, the insulation can be measured from one of the contacts, in particular a contact of the subset, to a point on the charging surface of the base body. This makes sure that there are no flows of current beyond the contacting area. This ensures sufficient touch protection.

A further aspect provides that the protective conductor check is only carried out if it has been previously determined that at least the subset of the plurality of contacts is contacted. This means that the protective conductor check also only takes place if a conductive connection has been detected beforehand.

In particular, the protective conductor check is only performed if the insulation check has been successfully performed beforehand. Accordingly, should an insulation fault be detected during the insulation check, the check routine is already aborted so that the protective conductor check is not carried out at all.

A further aspect provides that power contacts which are not part of the subset of the contacted contacts are switched potential-free. In particular, the switching positions of the contact switches which are associated with the power contacts that are switched potential-free are continuously monitored. This ensures the touch protection monitoring since it is made sure that power contacts that are connected potential-free will not inadvertently have a potential intended for the charging process.

According to a further aspect, a switch-off device is activated if it is determined during the continuous touch protection monitoring that the touch protection is not ensured. This is the case in particular if at least one of the contact switches is not in the intended switching position, which is assigned to a power contact that is not part of the subset of the contacted contacts. As an alternative or in addition, this is the case if the existing contacting of the at least one contact that is part of the subset of contacted contacts has broken.

The switch-off device may comprise a main switch, for example a contactor. The main switch can then be opened to provide electrical isolation.

Alternatively or additionally, the switch-off device may comprise an electronic power control that reduces the potential applied to a non-critical value.

In other words, the activation of the switch-off device corresponds to a fault protection, since the state of the contact switches is checked, with the main switch being opened in the event of a fault in order to switch the contacts potential-free and/or with the potential applied being reduced in value. Alternatively or additionally, this is done when the existing contacting suddenly breaks off or is not terminated in a controlled manner.

According to a further aspect of the invention, the power contacts each have a current path within the ground contact unit, with each current path having at least two switching elements assigned to it. This produces a redundancy, as a result of which, in the event of a fault in one of the switching elements, it can be ensured that the corresponding power contacts are nevertheless switched potential-free. The two switching elements are in particular one contact switch per power contact and a shared main switch for all power contacts. As already mentioned, the switch-off device can be activated when it is detected during the touch protection monitoring that, for example, a contact switch is switched such that the power contact coupled to it is assigned to a potential level, although it should be switched potential-free. This ensures that the corresponding power contacts, which should actually be switched potential-free, can be touched, since the respective potential has been completely switched off by means of the switch-off device or has been reduced to a low and non-critical level.

Moreover, a self-test of the power contacts may be performed in order to ensure that the contact switches of all power contacts are open. The self-test may in particular be performed before the contacting check and/or after a charging process has been effected and the contacting has been released. In this respect, two or more self-tests may be provided in a charging cycle, namely at the start of the charging cycle, even before the vehicle contact unit and the ground contact unit establish the conductive connection, and after a successful charging process, when the conductive connection has been deliberately released. This ensures that the power contacts or their contact switches are in the correct switching position if there is no contacting. The correct position of the respective contact switches means that all of the power contacts are switched potential-free. In principle, the self-test may, of course, also be carried out at other times.

Furthermore, the plurality of contacts may comprise at least one control contact by means of which the contacting check is performed. In particular, the plurality of contacts comprise at least two control contacts by means of which a contacting orientation of the vehicle contact unit is detected. The control contacts may be separately formed contacts of the plurality of contacts, i.e. contacts on the charging surface provided in addition to the power contacts and the protective conductor contact. The control contacts can be used to feed in a defined signal that cooperates with an associated control contact of the vehicle contact unit, whereby an electric circuit is closed in which the corresponding signal can be evaluated. If two control contacts are provided, which, in addition, have different signals applied to them, the orientation of the vehicle contact unit in relation to the ground contact unit can be determined when the conductive connection exists, i.e. the contacting orientation. Regardless of this, having two control contacts allows two channels to be formed, which creates a respective redundancy.

Generally, rather than the separately formed control contacts, special signals may also be used to carry out the contacting check, for example by using the power contacts to transmit special signals that are evaluated to determine whether a conductive connection exists. These signals may be high-frequency signals that run along a signal loop that comprises the ground contact unit and the vehicle contact unit.

A further aspect provides that during the insulation check, the insulation between the at least one control contact and one of the power contacts is checked. In this respect, the insulation between the control contact and neighboring contacts such as the power contacts is also checked. According to a further aspect, the contact across which the test current is passed during the protective conductor check is previously brought to a protective conductor level to which the protective conductor contact is assigned. The contact is connected to the protective conductor level by means of a relay. In other words, the contact may be a power contact that is adapted to be connected to the protective conductor level, for example ground or earth, by means of a respective relay. The appropriate test current can then be supplied by a current generator, for example an on-board current generator, through a contact, coupled to the respective power contact, of the vehicle contact unit, which is then discharged into the protective conductor level via the appropriately switched relay. A resistance can then be measured to determine whether the conductive connection exhibits an appropriate contact quality, as is desired.

The test current may have a current intensity of at least 200 mA. The resistance measured during the protective conductor check should not exceed a resistance value of 0.1 Ω, so that a protective conductor resistance threshold value of 0.1 Ω is provided, which is compared with the measured protective conductor resistance in order to ascertain the corresponding quality of the contacting.

Basically, the electric charging infrastructure is configured to carry out a method having the above-mentioned features. In this respect, the aforementioned features also constitute features of the electric charging infrastructure.

The respective contact switch may be in the form of a mirror contact and include a main contact and a monitoring contact, which are mechanically coupled but electrically isolated from each other.

The main contact and/or the monitoring contact of the contact switch may be a switch that has an open position and a closed position. In this respect, the main contact and/or the monitoring contact is/are constructed as a make and break switch. This means that the main contact and/or the monitoring contact can be shifted between an open position and a closed position. The advantage of the main contact being in the form of a switch having an open position and a closed position is, among other things, that the main contact cannot fuse during opening when it moves from its closed position, in which the charging current flows via the main contact, to a second position, which does not correspond to an open position but to a closed position with another counterpart, for example ground. During opening, an electric arc may be generated, which would then cause the main contact to fuse in the second (closed) position, so that it would no longer be possible for the main contact and therefore the entire contact switch to be shifted. This is effectively prevented if at least the main contact is in the form of a switch that has an open position and a closed position.

It may, however, also be provided that the main contact and/or the monitoring contact can be switched back and forth between two or more different, closed positions.

In any case, however, the main contact and the monitoring contact are electrically isolated from each other so that a common (closed) circuit is not formed via the two contacts, i.e. the main contact and the monitoring contact. The two contacts are thus not used to provide a charging functionality in one switching position of the contact switch and a sensor functionality or similar in the other switching position of the contact switch. Rather, the main contact and the monitoring contact are assigned to two circuits that are independent of each other and electrically isolated from each other.

Generally, monitoring may be performed during the charging process, but also before a charging process and/or after a charging process, particularly in connection with a self-test. Furthermore, monitoring may take place at cyclical intervals.

If a faulty or incorrect switching position is detected, a warning may be issued, for example a visual warning, an acoustic warning and/or a warning by means of a remote signaling contact. It may also be provided that charging is not possible, i.e. no charging process can be started, if a faulty or incorrect switching position was detected during the check.

For example, the measuring circuit which is used to carry out the voltage measurement on the at least one contact comprises a voltage divider and a comparator to which a reference voltage is applied. The voltage divider may comprise a first resistor (or a first capacitor) and a second resistor (or a second capacitor).

If two resistors are provided (resistive voltage divider), they differ in terms of the resistance value by at least a factor of 10, in particular by a factor of 100. A first resistor may have a resistance value of 1 M ohms, whereas a second resistor has a resistance value of 10 k ohms.

In the voltage divider, the first resistor (or the first capacitor) may be arranged between the monitored contact and a center tap.

The second resistor, i.e. the one having the lower resistance value, or the second capacitor is arranged between the center tap and the protective conductor level.

In this respect, provision may be made for the voltage divider to be a capacitive voltage divider if two capacitors are provided. A hybrid-type voltage divider may also be provided, which includes, for example, the first resistor and the second capacitor.

### BRIEF DESCRIPTION OF THE DRAWINGS

Further advantages and characteristics of the invention will be apparent from the description below and from the drawings, to which reference is made and in which:

FIG. 1 shows a schematic overview of a vehicle battery charging system which comprises an electric charging infrastructure according to the invention and a vehicle having a vehicle contact unit;

FIG. 2 shows a schematic top view of a ground contact unit of an electric charging infrastructure according to the invention;

FIG. 3 shows a schematic illustration of the electrical wiring of the power contacts of the ground contact unit according to FIG. 2; and

FIG. 4 shows a schematic overview of a process which comprises a method of checking a ground contact unit of an electric charging infrastructure.

### DETAILED DESCRIPTION

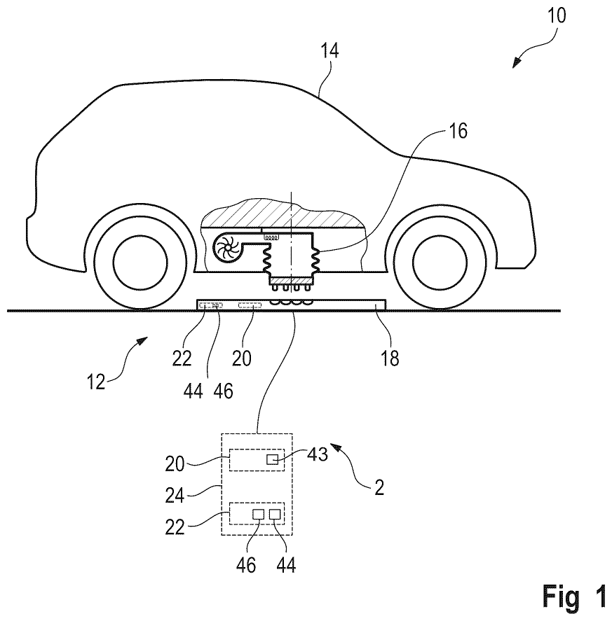

FIG. 1 shows a vehicle battery charging system 10, which shows an electric charging infrastructure 12 and an at least partially electrically operated vehicle 14, which includes a vehicle contact unit 16 that is adapted to establish a conductive connection with a ground contact unit 18 of the electric charging infrastructure 12 in order to charge a vehicle 14 battery, which is not illustrated in more detail here.

The electric charging infrastructure 12 includes a monitoring circuit 20 and a switch-off device 22, which may be fully integrated in the ground contact unit 18. Alternatively, the monitoring circuit 20 may be arranged partly in the ground contact unit 18 and partly in a monitoring unit 24 formed separately from the ground contact unit 18. Furthermore, provision may be made that the monitoring circuit 20 and the switch-off device 22 are both arranged entirely in the separately formed monitoring unit 24.

The separately formed monitoring unit 24 is therefore optional, for which reason it is shown in dashed lines in FIG. 1. Likewise, the monitoring circuit 20 and the switch-off device 22 are shown in dashed lines, since their respective positions may vary depending on the type of design.

In any case, the separately formed monitoring unit 24 would be electrically connected to the ground contact unit 18, as is indicated in FIG. 1.

In this respect, the electric charging infrastructure 12 comprises a checking system 25, which can be used to carry out checks, as will be discussed below.

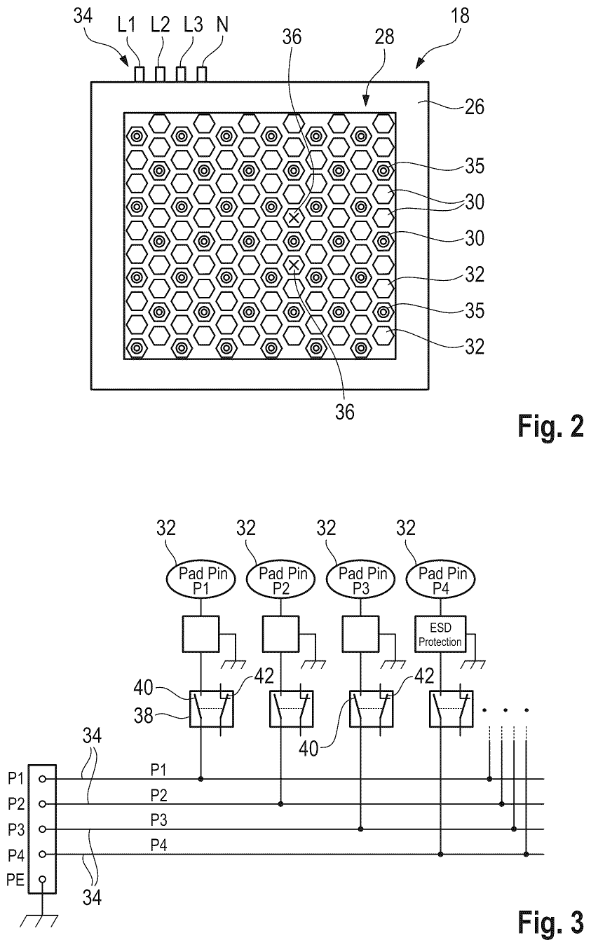

FIG. 2 shows the ground contact unit 18 in a top view according to a variant embodiment.

The ground contact unit 18 includes a plate-shaped base body 26 having a charging surface 28 which is exposed before the conductive connection is established. In other words, the charging surface 28 is thus an exposed charging surface when the contacting is established between the ground contact unit 18 and the vehicle contact unit 16.

However, the charging surface 28 may generally be covered by a cover (not illustrated here) when not in use, so that the charging surface 28 is protected from environmental influences. The respective cover can be removed manually or automatically, making the charging surface 28 freely accessible.

Provided on the charging surface 28 is a plurality of contacts 30, which may involve different kinds of contacts or types of contacts.

In any case, the contacts 30 include, inter alia, power contacts 32 which are utilized for the charging process of the battery of the vehicle 14 by assigning the power contacts 32 to a respective potential level 34.

In the embodiment shown, the ground contact unit 18 is designed as a three-phase ground contact unit, which means that the individual power contacts 32 can be assigned to the phases L1, L2 and L3 and a neutral phase N, which is also referred to as a neutral conductor. Accordingly, these are the corresponding potential levels N, P1, P2 and P3.

In addition to the power contacts 32, the contacts 30 include at least one protective conductor contact 35, i.e. a PE contact, with a plurality of protective conductor contacts 35 being provided in the embodiment shown, which are arranged on the charging surface 28 separately and insulated from the power contacts 32.

As an alternative to the embodiment shown in FIG. 2, the ground contact unit 18 may include a continuous protective conductor plane, which accordingly essentially corresponds to the surface area of the base body 26 or the base area of the charging surface 28. The individual power contacts 32 can then break through the respective protective conductor layer, the power contacts 32 each being insulated from the protective conductor plane, for example by ring-shaped sections.

Furthermore, the contacts 30 may also comprise at least one control contact 36, which is used for performing a contacting check.

In the embodiment shown, a plurality of control contacts 36 are provided, which have been drawn in only by way of example. The control contacts 36 can basically be used to determine whether the vehicle contact unit 16 has made contact with the ground contact unit 18.

In particular, the contacts 30 are generally distributed on the charging surface 28 and arranged in relation to one another such that at least two control contacts 36 are located in a contacting area of the charging surface 28 which is covered by the vehicle contact unit 16 when the conductive connection has been established. The two control contacts 36 in the contacting area can furthermore be used to determine the orientation in which the ground contact unit 18 has been contacted.

By knowing the geometry of the vehicle contact unit 16, it can moreover be determined which contacts 30 have been contacted, that is, which of the contacts 30 are part of the subset of the contacted contacts 30 that are located in the contacting area of the charging surface 28.

It can further seen in FIG. 3 that the power contacts 32, which are assigned to the four different potential levels, namely the phases L1, L2, L3 and the neutral phase N, are each assigned to the corresponding potential level 34 via a contact switch 38.

The contact switches 38 are therefore connected in series with the power contacts 32, as is apparent from FIG. 3.

The contact switches 38 are each designed as mirror contacts, so that the contact switches 38 include a main contact 40 and a monitoring contact 42. Due to their design as mirror contacts, it is ensured that the main contact 40, which acts as a relay, is mechanically coupled to the monitoring contact 42, so that the respective switching positions of the main contact 40 and the monitoring contact 42 presuppose each other or are mutually dependent. However, the main contact 40 and the monitoring contact 42 are electrically isolated from each other, so that the two contacts 40 and 42 are not associated with a common electric circuit. Rather, both contacts 40, 42 are assigned to different electric circuits, which are independent of each other and, in addition, electrically isolated from each other.

In this respect, there is no switching position of the contact switch 38 in which a closed circuit is formed in which both the main contact 40 and the monitoring contact 42 are involved, so that a current could flow across both contacts 40, 42 of the contact switch 38.

As shown in FIG. 3, the main contact 40 is designed as a normally open contact, i.e. an NO contact, whereas the monitoring contact 42 is designed as a normally closed contact, i.e. an NC contact.

FIG. 3 thus shows the initial position of the contact switches 38, since the contact switches 38 are each in a respective switching position in which the main contacts 40 are open, so that no current can flow to the power contacts 32. In other words, the power contacts 32 are not connected to any potential level 34, as a result of which touch protection is ensured.

The appropriate touch protection may be monitored by means of the charging infrastructure 12 in that the monitoring circuit 20 monitors, among other things, the respective switching position of the monitoring contacts 42 of the respective contact switches 38.

The monitoring here takes place at least for the contact switches 38 assigned to power contacts 32 which are not contacted when the conductive connection between the ground contact unit 18 and the vehicle contact unit 16 exists, that is, for power contacts 32 which are not part of the subset of the plurality of contacts 30 of the ground contact unit 18 that are contacted.

Alternatively or as a supplement, a measuring circuit 43 may be provided, for example as part of the monitoring circuit 20 and/or the monitoring system 25. The measuring circuit 43 is configured to perform the voltage measurement on the at least one of the contacts 30, in particular on one of the power contacts 32. This contact 30 may therefore also be referred to as a monitored contact.

The measuring circuit 43 is configured to detect an inadmissibly applied voltage at the monitored contact. The measuring circuit 43 may therefore be used to form a touch protection, since an inadmissibly applied voltage would be detected.

Irrespective of the type of detection, the monitoring circuit 20 activates the switch-off device 22 if the monitoring circuit 20 detects that there is an incorrect switching position at one of the monitoring contacts 42 and/or that there is an inadmissibly applied voltage, the consequence being that one of the main contacts 40 also has an incorrect switching position, since the monitoring contacts 42 and the main contacts 40 are mechanically coupled to one another.

The incorrect switching position here corresponds to an open switching position of the monitoring contact 42, which is accompanied by a closed switching position of the associated main contact 40, which would mean that a freely accessible power contact 32 would be assigned to a potential level 34 although this is not desirable since the respective power contact 32 is exposed.

An inadmissibly applied voltage here corresponds to a voltage applied to a freely accessible contact 30.

The switch-off device 22 changes its state due to its activation by the monitoring circuit 20, which may be accompanied by a complete switch-off or a complete disconnection. In other words, the switch-off device 22 may be designed such that an electrical isolation of all of the power contacts 32 is performed, as a result of which all of the power contacts 32 would be switched potential-free.

In this respect, the switch-off device 22 may comprise a main switch 44 or a contactor which performs the respective galvanic separation.

If the switch-off device 22 is integrated in the ground contact unit 18, two switching elements are provided in a current path within the ground contact unit 18, which are connected in series, specifically the respective contact switches 38 and the main switch 44.

Alternatively, the switch-off device 22 may comprise an electronic power control 46, which is provided to reduce the voltage associated with the potential level 34 accordingly, so that the voltage applied is limited to a non-critical value, thereby ensuring the touch protection. In other words, so low a voltage is applied to the respective power contact 32, which is coupled to the erroneously closed main contact 40 of the contact switch 38, that there is no danger.

This can also be appropriately checked by the measuring circuit 43 by conducting another voltage measurement on the monitored contact. After regulation by the electronic power control 46 has been effected, the voltage measured should now be below a limit value. This ensures touch protection.

FIG. 1 already showed that both the monitoring circuit 20 and the switch-off device 22 may be arranged partly in the ground contact unit 18 and partly in the separately formed monitoring unit 24.

If the monitoring circuit 20 comprises two subcircuits, it may be provided that the first subcircuit is integrated in the ground contact unit 18 and outputs at least one output signal of the ground contact unit 18 to the second subcircuit of the monitoring circuit 20, which is integrated in the separately formed monitoring unit 24.

The at least one output signal can transmit the state of the entire ground contact unit 18 here, for example in the form of a binary signal, that is, “ok” or “not ok”, whereby the monitoring circuit 20, in particular the second subcircuit, then activates the switch-off device 22 accordingly, so that the switch-off device 22 changes its state.

With the aid of the monitoring circuit 20, a continuous touch protection monitoring of the power contacts 32 thus takes place in that switching positions of the contact switches 38 are continuously monitored which are associated with power contacts 32 that are not part of the subset of the contacted contacts 30. Alternatively or additionally, a voltage measurement may be carried out on at least one of the contacts 30, in particular on one of the power contacts 32.

In addition to this continuous touch protection monitoring, provision may further be made that a continuous touch protection monitoring is performed by continuously monitoring an existing contacting of at least one contact 30 that is part of the subset of contacted contacts 30. This may be the control contact 36, a power contact 32 and/or one of the protective conductor contacts 35.

For appropriate monitoring, a signal, for example a high-frequency signal, can be fed in via one of the corresponding contacts 30; an interruption of the corresponding signal would be detected if the conductive connection were to break.

In this way, a faulty control of one of the contact switches 38 can basically be detected, for example as caused by a problem with the (control) electronics and/or by a software problem. Such a detection or monitoring is possible in particular while a charging process is carried out.

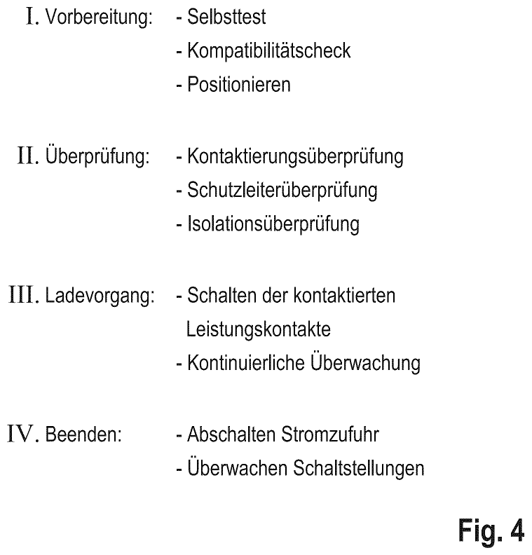

It is further apparent from FIG. 4 that, in addition to continuous touch protection monitoring, further checks take place, in particular before a charging process is initiated.

In preparation for the charging process, a self-test of the power contacts 32 can first be carried out to ensure that the contact switches 38 of all power contacts 32 are open. This may be performed at the beginning to make sure that the ground contact unit 18 is basically in a condition that allows a charging process to be carried out at all.

To this end, the positions of the contact switches 38, in particular of the monitoring contacts 42, can be monitored by means of the monitoring circuit 20, as has already been described above with regard to the continuous touch protection monitoring.

Furthermore, the preparation phase comprises a compatibility check in which communication takes place between the ground contact unit 18 and the vehicle contact unit 16 of the vehicle in order to determine whether the two contact units 16, 18 are able to carry out a charging process together at all. Here, suitable signals can be exchanged with each other in order to determine whether the contact units 16, 18 are compatible with each other.

Subsequently, during the preparation phase a positioning can take place, in which the vehicle 14 is positioned over the ground contact unit 18 or in relation to it, for example by appropriate signals being displayed to a driver of the vehicle 14 so that the driver will park the vehicle 14 as exactly as possible over the ground contact unit 18, as a result of which a conductive connection can be established. This allows the size of the ground contact unit 18 to be minimized.

The vehicle 14 or the vehicle contact unit 16 will then send a charging request to the electric charging infrastructure 12, in particular the ground contact unit 18. The electric charging infrastructure 12 processes the charging request accordingly. If the result is positive, this is communicated to the vehicle 14 or the vehicle contact unit 16, whereupon the charging process could be initiated.

For this purpose, first the conductive connection is established between the vehicle contact unit 16 and the ground contact unit 18 by moving at least one component of the vehicle contact unit 16 toward the ground contact unit 18, causing this component to come to rest in some areas on the charging surface 28 of the ground contact unit 18, so that at least a subset of the plurality of contacts 30 of the ground contact unit 18 is contacted.

In order to ascertain this, the contacting check is carried out, in which it is determined whether contacts 30 of the ground contact unit 18 have been contacted. In addition, it can be determined which of the respective contacts 30 have been contacted, by interconnecting them individually and/or in groups.

To this end, high-frequency signals may be provided, which are routed via the power contacts 32. Alternatively, provision may be made for this to be done via the control contacts 36. The control contacts 36 can carry different signals, as a result of which, in addition to simply determining which contacts 30 are occupied, it is also possible to determine the contacting orientation of the vehicle contact unit 16 in relation to the ground contact unit 18.

Depending on the contacting check carried out, the power contacts 32 could then be assigned to specific potential levels 34.

During the checking phase, a protective conductor check also takes place, in which a test current is passed across at least one contact 30 of the plurality of contacts 30 in order to establish a contact quality of the existing conductive connection between the vehicle contact unit 16 and the ground contact unit 18.

For this purpose, the vehicle 14 may comprise a current generator or a signal generator providing the test current that is conducted via one of the contacts of the vehicle contact unit to a contact 30, coupled thereto, of the contacts 30 of the ground contact unit 18.

For example, one of the power contacts 32 may be used, which is coupled to a corresponding power contact of the vehicle contact unit 16, the corresponding power contact 32 of the ground contact unit 18 having been switched to the protective conductor level, which corresponds to the level of the protective conductor contact 35. To this end, a relay may be provided, via which the respective contact 30 is connected to the protective conductor level.

Subsequently, a resistance can then be measured in order to ascertain the contact quality. Here, the resistance measured should not exceed a resistance value of 0.1 Ω, so that a protective conductor resistance threshold value of 0.1 Ω is provided. The test current used should have a current intensity of at least 200 mA.

Alternatively, provision may also be made for the test current to be provided by the ground contact unit 18.

A further step provides for an insulation check to be carried out during the checking in order to make sure that there are no leakage currents or the like between contacts 30 or other areas of the ground contact unit 18.

The insulation check may basically be carried out between two contacts 30 by applying a test voltage and measuring an insulation resistance that is compared to a predefined insulation resistance threshold value. For example, the test voltage is at least 500 V. The insulation resistance threshold value is, for example, 0.25 MΩ.

The two contacts 30 that are used for the insulation check may be neighboring contacts on the charging surface 28, in particular two contacts 30 of the subset of contacts 30 that are contacted when the conductive connection exists. An (unintentional) conductive connection is most likely to occur between neighboring contacts 30, for example through an object, dirt or moisture. In particular, the insulation check is carried out between two power contacts 32. Alternatively or additionally, it may be provided that the insulation check is carried out between at least one power contact 32 and the at least one protective conductor contact 35. The insulation check may also be performed between at least one power contact 32 and the control contact 35.

Also, during the insulation check, the insulation from a contact 30 of the subset to a point on the charging surface 28 of the base body 26 can be measured.

Basically, it may be provided that the insulation check is only carried out if it has been previously determined that at least a subset of the plurality of contacts 30 is contacted at all, that is, a conductive connection is provided.

Furthermore, the protective conductor check can also only be carried out if it has been previously determined that a conductive connection exists, i.e. that at least the subset of the plurality of contacts 30 is contacted. In addition, the protective conductor check can also only be carried out if the insulation check has been carried out successfully beforehand.

After the check has been carried out and all checking steps have been successfully completed, the charging process can start.

As already discussed above, the power contacts 32 that are not part of the subset of the contacted contacts 30 have already been switched potential-free, which was also checked during the self-test during preparation.

In this respect, only the power contacts 32 of the corresponding potential level 34 that are part of the subset of the contacted contacts 30 are connected.

A charging current then flows from the ground contact unit 18 into the battery of the vehicle 14 by way of the vehicle contact unit 16, which has established the conductive connection with the ground contact unit 18, resulting in the battery being appropriately charged.

During the charging process, continuous touch protection monitoring takes place, as has already been discussed. In this process, it is determined, by continuously monitoring a contact 30 of the subset of contacted contacts, for example the control contact 36, whether only the contacted power contacts 32 of a corresponding potential level 34 are actually connected or whether the existing contacting does not break off during the charging process.

If it is determined that the touch protection is no longer ensured, the switch-off device 22 is activated by the monitoring circuit 20, as a result of which either the main switch 44 is opened to provide electrical isolation, and/or the electronic power control 46 down-regulates the respective potential until a non-critical value of the voltage has been reached. The non-critical value may be a voltage that is safe, in particular an alternating voltage below 25 V, i.e. 25 VAC, or a direct voltage of 60 V, i.e. 60 VDC.

After the charging process has been completed, the conductive connection between the vehicle contact unit 16 and the ground contact unit 18 is disconnected.

To this end, the previously connected power contacts 32, which belong to the subset, are first switched potential-free by activating the respective contact switches 38. In addition, the switch-off device 22 may also be activated accordingly, for example to provide electrical isolation by means of the main switch 44. This provides redundancy. In addition, another check may be performed to make sure that all of the power contacts 32 are potential-free, by monitoring the associated monitoring contacts 42 by means of the monitoring circuit 20.

The conductive connection is subsequently released by causing the vehicle contact unit 16 to be disengaged so that there is no longer any contact with the ground contact unit 18. The vehicle 14 can then leave the electric charging infrastructure 12.

In conclusion, another self-test may be carried out by determining whether all of the power contacts 32 are in their potential-free state, that is, whether all of the associated contact switches 38 are in the non-current-carrying state, which is the case when the corresponding main contacts 40 are open and/or the monitoring contacts 42 are closed.

Basically, the self-test may, of course, also be carried out at other times. This means that self-tests can be carried out at multiple points in time, for example cyclically, in order to continuously check the readiness of the electric charging infrastructure 12, in particular that of the ground contact unit 18.

In this respect, it is ensured that the vehicle 14 can be efficiently electrically charged by making a conductive connection. At the same time, appropriate safety precautions are taken by checking whether the ground contact unit 18 is in a state that is suitable for a charging process.

The sequence shown in FIG. 4 and the associated method can in principle be carried out by the electric charging infrastructure 12, which is appropriately configured for this purpose.

1. A method of checking a ground contact unit of an electric charging infrastructure, wherein the ground contact unit has a plate-shaped base body and a plurality of contacts which are arranged on a charging surface of the base body, against which a vehicle contact unit can come to rest, wherein the plurality of contacts comprise at least one protective conductor contact and power contacts which are assigned to at least one potential level via at least one contact switch, the method comprising steps of:
performing a contacting check to determine whether at least a subset of the plurality of contacts of the ground contact unit is contacted;
performing a protective conductor check to ascertain a contact quality by passing a test current across at least one contact of the plurality of contacts; and
performing continuous touch protection monitoring of the contacts by continuously monitoring switching positions of the contact switches which are assigned to power contacts that are not part of the subset of the contacted contacts, and/or by continuously monitoring an existing contacting of at least one contact that is part of the subset of the contacted contacts and/or by performing a voltage measurement on at least one of the contacts.

2. The method according to claim 1, wherein the subset of the plurality of contacts is associated with a contacting area of the charging surface, which is covered by a component of the vehicle contact unit when a conductive connection is established between the ground contact unit and the vehicle contact unit.

3. The method according to claim 1, wherein an insulation check is carried out between two contacts by applying a test voltage and measuring an insulation resistance which is compared with a predefined insulation resistance threshold value.

4. The method according to claim 3, wherein the two contacts used in the insulation check are neighboring contacts on the charging surface, in the subset.

5. The method according to claim 3, wherein the insulation check is only carried out if it has been previously determined that at least the subset of the plurality of contacts is contacted.

6. The method according to claim 3, wherein during the insulation check, the insulation from one of the contacts, in the subset, to a point on the charging surface of the base body is measured.

7. The method according to claim 3, wherein the protective conductor check is only performed if it has been previously determined that at least the subset of the plurality of contacts is contacted.

8. The method according to claim 7, wherein the protective conductor check is only performed if the insulation check has been successfully performed before.

9. The method according to claim 1, wherein power contacts which are not part of the subset of the contacted contacts are switched potential-free, wherein the respective switching positions of the contact switches which are associated with the power contacts that are switched potential-free are continuously monitored.

10. The method according to claim 1, wherein a switch-off device is activated if it is determined during the continuous touch protection monitoring that the touch protection is not ensured, wherein if at least one of the contact switches is not in an intended switching position, which is assigned to a power contact that is not part of the subset of the contacted contacts, and/or the existing contacting of the at least one contact that is part of the subset of the contacted contacts has broken.

11. The method according to claim 1, wherein the power contacts each have a current path within the ground contact unit, wherein each current path has at least two switching elements assigned to it, including one contact switch per power contact and a shared main switch for all power contacts.

12. The method according to claim 1, wherein a self-test of the power contacts is performed in order to ensure that the contact switches of all power contacts are open, wherein the self-test is performed before the contacting check and/or after a charging process has been effected and the contacting has been released.

13. The method according to claim 3, wherein the plurality of contacts comprise at least one control contact by means of which the contacting check is performed, wherein the plurality of contacts comprise at least two control contacts by means of which a contacting orientation of the vehicle contact unit is detected.

14. The method according to claim 13, wherein during the insulation check the insulation between the at least one control contact and one of the power contacts is checked.

15. The method according to claim 1, wherein the contact across which the test current is passed during the protective conductor check has previously been brought to a protective conductor level with which the protective conductor contact is associated, in wherein the contact is connected to the protective conductor level via a relay.

16. An electric charging infrastructure for establishing a conductive connection to a vehicle contact unit, wherein the charging infrastructure includes a ground contact unit which has a plate-shaped base body and a plurality of contacts which are arranged on a charging surface of the base body, against which the vehicle contact unit can come to rest, wherein the plurality of contacts omprise at least one protective conductor contact and power contacts which are assigned to at least one potential level via at least one contact switch, and wherein the charging infrastructure includes a checking system which is configured to:
perform a contacting check to determine whether at least a subset of the plurality of contacts of the ground contact unit is contacted;
perform a protective conductor check to ascertain a contact quality, wherein the checking system is configured to pass a test current across at least one contact of the plurality of contacts; and
perform a continuous touch protection monitoring of the contacts, the checking system being configured to continuously monitor switching positions of the contact switches which are assigned to power contacts that are not part of the subset of the contacted contacts, and/or to continuously monitor an existing contacting of at least one contact that is part of the subset of the contacted contacts, and/or to perform a voltage measurement on at least one of the contacts.
